(19) United States
(12) Patent Application Publication
(10) Pub. No.: US 2020/0335482 A1
(43) Pub. Date: Oct. 22, 2020

(54) SYSTEM AND METHOD FOR CHIP-ON-BOARD LIGHT EMITTING DIODE

(71) Applicants: BARCO N.V., kortrijk (BE); IMEC VZW, Heverlee (BE); UNIVERSITEIT GENT, Gent (BE)

(72) Inventors: Saso MLADENOVSKI, Gent (BE); Jasper Irene LAMBERT, Waregem (BE); Stephanie Cyriel Adrianna VAN HAECKE, Sint-Amandsberg (BE); Floris Albert BONTINCK, Destelbergen (BE); Jindrich WINDELS, Gent (BE); Michal JABLONSKI, Cieszyn (PL)

(73) Assignees: BARCO N.V., Kortrijk (BE); IMEC VZW, Heverlee (BE); UNIVERSITEIT GENT, Gent (BE)

(21) Appl. No.: 16/764,011

(22) PCT Filed: Nov. 12, 2018
(86) PCT No.: PCT/EP2018/080952

§ 371 Date: May 14, 2020

(30) Foreign Application Priority Data
Nov. 14, 2017 (GB) 1718818.6
Nov. 16, 2017 (GB) 1719009.1

(51) Int. Cl. H01L 25/075; H01L 33/60; H01L 27/32; H01L 33/52; H01L 33/00

(52) U.S. Cl. CPC H01L 25/0753; H01L 33/60; H01L 27/3244; H01L 2933/0058; H01L 33/0095; H01L 2933/0091; H01L 2933/005; H01L 33/52

(57) ABSTRACT

An LED array mounted on a circuit board including a plurality of LED chips embedded in an encapsulant. Each LED chip is placed inside a cavity which is made up solely from a multilayer foil and attached to the circuit board with an adhesive film. The foil cavity design enables a variety of mounted LED arrays to be manufactured with the same process.

The present invention relates to the provision of an encapsulated array of solid state light sources such as OLED's or LED's, or a method of making an encapsulated array of solid state light sources such as OLED's or LED's.

### BACKGROUND

There is an increasing demand for high resolution displays implemented with light emitting diodes where the desired pixel pitch is e.g. 6 mm or 3 mm or less. These small dimensions make it difficult, or impossible, to use conventional LED component packaging, and it is often preferable to place the chips directly on the electronic circuit board with chip-on-board (COB) technology. In order to protect the naked chip from the environment and mechanical damage, an encapsulant is usually added. A structure or cavity to hold the encapsulant, at least while in liquid form, needs to be added to the circuit board. Molding is a commonly used technique to provide these cavities. A disadvantage is that such mold will mostly have a gap towards the circuit board. If the mold is e.g. used for shaping the encapsulant, the encapsulant in its liquid form before curing can enter the gap resulting in a base layer of encapsulant under the mold. This can give rise to light leakage (so-called optical cross talk) which is highly unwanted. If the mold is used for shaping the side walls of the cavity (e.g. with a dark material in order to absorb light), the side wall material can enter in the gap and flow over the LED itself, which is of course highly unwanted. A further disadvantage with molding techniques is that when the cavity wall is finalized and one defect LED is discovered, the whole board has to be scrapped.

A conventional technique to add the encapsulant is to use (micro-) dispensing. This comprises a robotic arm having a needle at its end so that the encapsulant is placed around each chip through the needle. Even if the robot arm works with high speed, the total time to fill a circuit board is substantial.

U.S. Pat. No. 8,330,176B2 discloses an LED device having a “removable protective layer” with an absorptive or reflective layer. The removable protective layer is disposed onto a substrate, which is a circuit board. Thus, the reflecting cups are created by shaping the circuit board itself. If the individual LEDs should not be diced and one LED fails, the whole LED board has to be scrapped.

U.S. Pat. No. 8,330,176B2 does not teach how to incorporate the reflective cups in the removable protective layer.

### SUMMARY OF THE INVENTION

Embodiments of the present invention avoids one or more of the above mentioned deficiencies.

In one aspect of the present invention a solid state light source such as an OLED or LED array is provided for imaging applications mounted on a substrate comprising a plurality of solid state or OLED or LED chips, a multilayer foil having holes and being attached to the substrate with an adhesion promoting film, a solid state chip such as an OLED or LED chip is disposed within each hole, the thickness of the foil is equal to or larger than the height of the disposed solid state chip or OLED or LED chip, each hole is filled with an optical encapsulant, wherein walls of the holes in the foil define the structure that keeps the encapsulant around the LED chip in a direction perpendicular to the substrate. The walls of the holes are preferably the only structure that keeps the encapsulant around the solid state or OLED or LED chip in a direction perpendicular to the substrate. This array can be configured in many ways without requiring a change in expensive tooling.

Each hole can be defined by a wall or edge and a spacing between the wall or edge of each hole and the solid state light source such as an OLED or LED chip which is placed in each hole. After placement of the chip a part of the substrate is exposed in the spacing. Preferably the edge or wall extends down towards the substrate and in fact touches the substrate all around the hole.

An advantage of this construction is that the multilayer foil is adapted to be removed and replaced with a new multilayer foil having holes in the same positions. The optical encapsulant can be arranged to be removed, and any of the solid state light sources such as an OLED or LED component is arranged to be replaced. The result is that no component of the multilayer foil is sandwiched between the solid state light source such as the OLED or LED chip and the substrate.

Accordingly, an embodiment of the present invention relates to a multilayer foil having holes and being attached to a substrate with an adhesive promoting film, a solid state light source such as an OLED or LED chip is disposed within each hole, each hole being defined by an edge or wall and the edge or wall of each hole is spaced from the solid state light source such as the OLED or LED chip in that hole, the thickness of the foil being equal to or larger than the height of the disposed solid state light source such as the OLED or LED chip, each hole being filled with an optical encapsulant, wherein edges or walls of the holes in the foil define the structure that keeps the encapsulant around the LED chip in a direction perpendicular to the substrate.

The uppermost layer in the multilayer foil can absorb or reflect visible light. For example the multilayer foil can comprise an absorbing layer for visible light or a reflecting layer for visible light. This allows adjusting of optical properties such as visibility of the solid state light sources such as OLED's or LED's in differing ambient lighting conditions. Additionally, the efficiency of the pixels can be adjusted, where the efficiency can be defined as the ratio between the power of emitted visible light of a pixel and the electrical input driving power of the pixel.

The optical encapsulant can be made so that it is higher or lower than the uppermost layer of the multilayer foil or is flush with the uppermost layer of the multilayer foil. This allows light exit angular distributions to be controlled. For example the optical encapsulant can comprise visible light absorbing particles, wherein a pixel comprises the optical encapsulant layer with the absorbing particles, the substrate and the solid state light sources such as OLED's or LEDs. Alternatively or in addition the optical encapsulant can comprise visible light scattering particles. It is advantageous that the visible light absorbing and/or visible light scattering particles can determine an angular distribution of light emitted from a cavity. For example the angular distribution can have a Lambertian or cosine intensity profile. Additionally, the light absorbing or light scattering particles can determine the amount of ambient light reflected from the pixel. Furthermore, the above mentioned efficiency of the pixels can be adjusted.

In another aspect of the present invention, a method for assembling a solid state light source array or an OLED or LED array is provided comprising a PCB having OLED's or LED's mounted onto it, an adhesive multilayer foil having holes and an optical encapsulant, the method comprising the steps of placing the multilayer foil onto the PCB so that the OLED's or LED's are positioned in the holes, laminating the multilayer foil onto the PCB, applying optical encapsulant on top of the multilayer foil and removing any excess, and curing the optical encapsulant.

The step of applying the optical encapsulant can comprise any of heat curing the optical encapsulant, photocuring the encapsulant, room temperature curing of the encapsulant.

The step of applying the optical encapsulant can comprise applying the optical encapsulant under vacuum.

It is particularly advantageous that after the multilayer foil has been placed on the PCB and before the optical encapsulant has been cured, the multilayer foil can be removed, the optical encapsulant can be removed, if any is present, any failed component can be replaced, a new multilayer foil having holes can be placed onto the PCB so that the OLED's or LED's are positioned in the holes, the multilayer foil can be laminated onto the PCB, optical encapsulant can be applied on top of the multilayer foil and any excess can be removed, and the optical encapsulant can be cured. By this process a failed device can be renewed.

Although the present invention has been described with reference to solid state light sources other solid state electronic devices can be used instead of solid state light sources such as microprocessors, microcontrollers, ultrasound emitters, radar emitters, sensors of all types such as pressure or temperature sensors, etc.

### BRIEF DESCRIPTION OF DRAWINGS

FIG. 1 shows an embodiment of the present invention comprising an array of LED's.

FIG. 2 shows a top view of an embodiment of the present invention comprising a multiple of LED's surrounded by a multilayer foil.

FIG. 3 shows a cross sectional view of an embodiment of the present invention comprising an LED surrounded by a multilayer foil.

FIG. 4 shows an embodiment of the present invention comprising an encapsulant with a filler material, e.g. micro particles.

### DEFINITIONS

A “chip-on-board” or “COB” or “OLED Chip” or “LED Chip” is a chip that can be connected directly to a printed circuit board, e.g. by wiring or flip-chip soldering. The chip is usually covered with a coating of resin such as epoxy to protect the chip (and possible wires) from the environmental degradation by heat, humidity, sulphur, oxygen, etc., as well as to protect from mechanical damage. In comparison with a conventional heat sink, COB's are also advantageous in that they require little physical space.

An “optical encapsulant” or “OE” is a material used to seal up and cover a device or circuit for mechanical and environmental protection. Such an encapsulant can be translucent or transparent. It can be a potting compound. In the field of LED's this encapsulant can comprise e.g. epoxy or acrylic resins or silicone (PDMS-Polydimethylsiloxane) based elastomers. The encapsulant can include particles and/or colorants. The particles can be visible light scattering or visible light absorbing particles.

An “adhesive or adhesion promoting film” (APF) is a film that enables adhesion between two surfaces. It can comprise different types of adhesion technology, for example pressure sensitive adhesion material or adhesive where adhesion is initiated by applying a pressure. Heat sensitive adhesion can be based on e.g. thermoplastic co-polymers that can be softened by heating and providing a good adhesion between the surfaces, when cooled down.

### DESCRIPTION OF ILLUSTRATIVE EMBODIMENTS OF THE PRESENT INVENTION

Embodiments of the present invention provide cavities for light sources such as solid state light sources of which LED's or OLED's are example. These solid state light sources can be electrically and mechanically connected to a substrate such as a wiring substrate or PCB. These cavities can be aligned accurately with the positions of the solid state light sources such as OLED's or LED's.

Embodiments of the present invention provide an array of solid state light sources such as OLED or LED chips or dies disposed on a wiring substrate such as a PCB. A removable multilayer foil having a plurality of holes is disposed on the substrate on the same side or each side where the array of solid state light sources such as OLED or LED chips or dies are present. One hole can be aligned or registered with at least one solid state light source such as OLED or LED chips or dies. An encapsulant encapsulates each solid state light source such as OLED or LED chip or die. The array of solid state light sources such as OLED or LED chips or dies can comprise the encapsulant including means to control the beam of light emitted from the holes, e.g. may include a lens or particles such as visible light scattering particles and/or visible light absorbing paricles.

The wiring substrate and the walls of the holes form a cup and depending upon the materials used for the multilayer foil, a visible light reflecting cup can be formed.

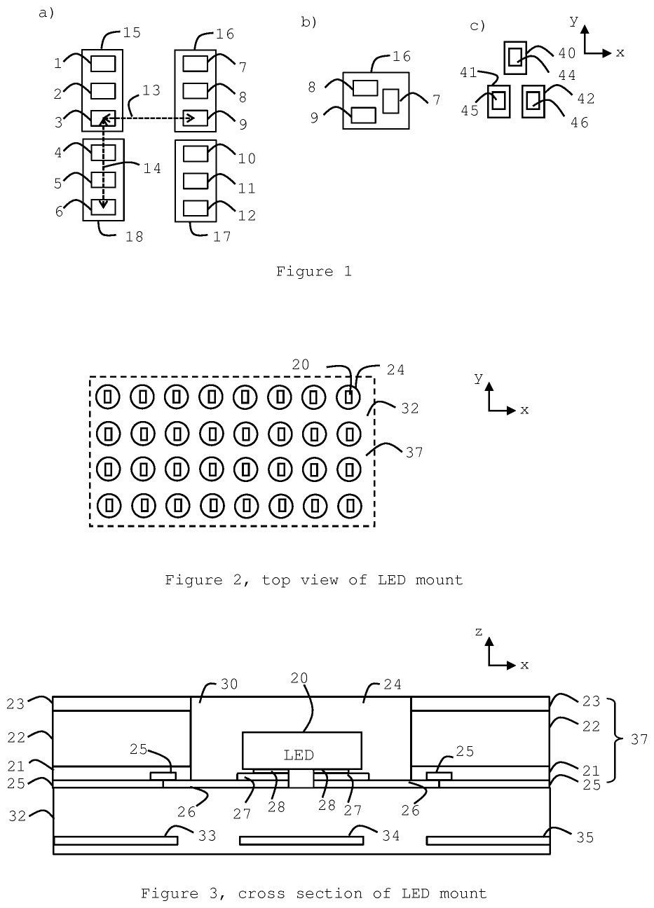

FIG. 1a) shows a top view of an embodiment of the present invention comprising an array of light emitting light sources such as solid state light sources for example OLED's or LED's. These can be RGB OLED's or LED's 1-12 that are distributed over an area in the x- and y directions. Each light emitting light source, preferably solid state light source such as an OLED or LED, for example RGB OLED or LED 15, 16, 17, or 18 can comprise a red, green and a blue OLED or LED. The pixel pitch is the distance between the nearest two neighbouring light emitting light sources, preferably solid state light sources, for example OLED's or LED's of the same colour e.g the length of arrows 13 or 14. When the light emitting light sources, preferably solid state light sources, such as for example OLED's or LED's are used for high-resolution displays, the pixel pitch may be in the order of 1-6 mm. Additionally or alternatively, the layout can comprise one or more cavities having a rotated position, as in FIG. 1b). This enables a more compact design. FIG. 1c) describes another embodiment of the present invention comprising cavities 40, 41 and 42 and LED's or OLED's 44, 45 and 46. A design can be beneficial in case of e.g. blue-LEDs being used with photoluminescent materials (e.g. Quantum Dots, Phosphors or Quantum platelets), or when using “virtual pixels”, i.e. one color sub-pixel is shared among 2 groups of pixels and the content is managed time-sequentially. “Virtual pixels” are created by using a group of sub-pixels whose optical centre is determined by which combination of color sub-pixels are driven.

FIG. 2 shows a top view (in the xy plane) of an embodiment of the present invention where a multiple of light emitting light sources, preferably solid state light source, such as for example OLED's or LED's 20 are mounted onto a PCB (Printed Circuit Board) 32. Each light emitting light source, for example OLED or LED 20 is placed inside a cavity 24. The optical axis of each light source, preferably solid state light source can be parallel to the central axis of the cavity.

FIG. 3 shows a side view, or cross-section (in the xz plane), of an embodiment of the present invention comprising light emitting light source, preferably solid state light source, for example an OLED or LED 20 mounted on a wiring substrate such as a printed circuit board, PCB, 32 inside a cavity 24. The light emitting light source, preferably solid state light source, for example OLED or LED 20 is placed inside a cavity 24 which is enclosed by a multilayer foil 37 and the circuit board 32. The circuit board may have electrical contacts 26 on the side facing the cavity. The multilayer foil 37 comprises an optical foil 22, a top layer 23 and an adhesive layer 21, which are designed to have long-term adhesion to each other and to the interfacing surface of the circuit board, which may comprise a solder mask 25. The wiring substrate or PCB 32 can comprise electrical conductors 33-35 that can be connected to the electrical contacts 26 with via holes. The electrical contacts 28 of the light emitting light source, preferably solid state light source, for example OLED or LED 20 can be connected to the electrical contacts 26 of the PCB 32 via conductive contact materials 27, e.g. solder joints or conductive adhesives. The cavity 24 can be filled with an optical encapsulant 30. In some embodiments, the multilayer foil 37 may comprise additional or other layers than what is described in FIG. 3.

Each hole can be defined by a wall or edge and a spacing between the wall or edge of each hole and the solid state light source such as an OLED or LED chip which is placed in each hole. After placement of the chip a part of the substrate is exposed in the spacing. Preferably the edge or wall extends down towards the substrate and in fact touches the substrate all around the hole.

An advantage of this construction is that the multilayer foil is adapted to be removed and replaced with a new multilayer foil having holes in the same positions. The optical encapsulant can be arranged to be removed, and any of the solid state light sources such as an OLED or LED component is arranged to be replaced. The result is that no component of the multilayer foil is sandwiched between the solid state light source such as the OLED or LED chip and the substrate.

Accordingly, an embodiment of the present invention relates to a multilayer foil having holes and being attached to a substrate with an adhesive promoting film, a solid state light source such as an OLED or LED chip is disposed within each hole, each hole being defined by an edge or wall and the edge or wall of each hole is spaced from the solid state light source such as the OLED or LED chip in that hole, the thickness of the foil being equal to or larger than the height of the disposed solid state light source such as the OLED or LED chip, each hole being filled with an optical encapsulant, wherein edges or walls of the holes in the foil define the structure that keeps the encapsulant around the LED chip in a direction perpendicular to the substrate.

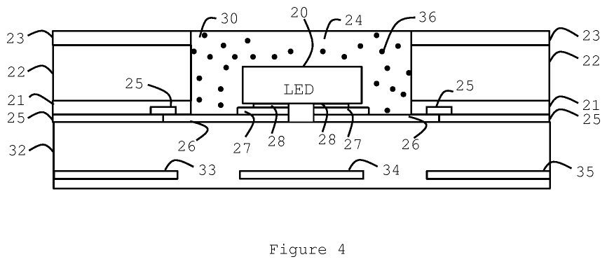

The top layer 23 can be made with arbitrary materials suitable for the application. In many cases an optically absorbing material is preferable in order to reduce reflection of ambient light. By implementing a structure in said layer, the absorption of ambient light can be further increased. The optical foil 22 can be adapted to various applications requiring high or low output of the light emitting light source, preferably solid state light source, for example the OLED or LED light. For applications in low or intermediate levels of ambient light a dark tinted foil will provide good contrast. This could further be emphasized by adding absorbing particles 36—see FIG. 4, (e.g. carbon black or other filler material, e.g. micro particles) to the optical encapsulant.

Additionally a dark tinted PCB material may be used. The reduced ambient light will increase contrast for the output of the light emitting light source, preferably solid state light source, for example the OLED or LED output, especially when showing dark colours.

For applications where high brightness and high efficiency is necessary, for example in high levels of ambient light, a light coloured- or metallic foil can be used. Additionally a white or reflective PCB material can be used.

Additionally, scattering particles 36—see FIG. 4, e.g. a filler material such as micro particles, can be added to the optical encapsulant, for example titanium dioxide. The top layer 23 put on top of an optical foil 22 that is reflective, can still be absorbing. This can be advantageous in that it reduces secondary reflections arising from the light that is generated by the display itself.

Embodiments of the present invention can involve the possibility of creating the light emitting light source, preferably solid state light source, for example OLED or LED cavity with solely a multilayer foil. The cavity or holes can be obtained by substractive manufacture such as e.g. laser cutting or punching. The mounting of the multilayer foil onto the PCB can be made with adhesives that provide a good long-term fixation to the PCB. Since the mounting process can be independent of the layout of holes in the multilayer foil, the same assembly process can be used for different designs. Apart from the above mentioned different material choices of the optical foil (and the top layer), the fill factor may also depend on the application. For e.g. outdoor applications it is desirable with a deep cavity so that a higher amount of protective encapsulant covers the solid state light source such as an OLED or LED chip. If the cavity is made deeper it also may have to be made wider in order to overcome the cavity wall shadowing of outgoing OLED or LED light at high angles. Consequently, wide cavities also have to be placed further apart. For indoor applications, e.g. cinema, the encapsulant can be made thinner so that the cavity will be more shallow and narrow. The cavities can then be placed closer to each other, providing higher pixel pitch and higher resolution.

Hence, the present invention provides a flexible design that can easily be adapted for different applications while the actual assembly process remains the same. The present invention is indeed suitable for RGB OLED's or LED's, but it can also be used for OLED's or LED's based on colour conversion technology. Such 0lED's or LEDs can comprise coatings (e.g. based on phosphor), Quantum Dots or the more recent quantum platelets, for converting the color of an OLED or LED to another color. (Quantum Platelets are a few nanometer-sized rectangles a few atomic layers thick). The multilayer foil can easily be adapted to comprise differently shaped cavities intended for a mix of e.g. the above mentioned OLED or LED types.

After the multilayer foil has been placed onto the PCB, the optical encapsulant can be disposed on top of the foil and excess encapsulant can be removed with e.g. a blade or a squeegee, which is much faster than using micro-dispensing techniques. A further advantage with the present invention is that in any step before the optical encapsulant has been cured, the PCB can be checked by e.g. camera inspection. If necessary, it is possible to remove the whole multilayer foil/cavity structure. For example, if an OLED or LED has failed, the multilayer foil can be removed and the failed OLED or LED can be replaced. For a conventional molded and cured cavity structure, a failed OLED or LED means that the whole board would have to be scrapped. Also if the multilayer foil/cavity structure turns out to not laminate sufficiently to the PCB, it can easily be replaced. The corresponding situation with a molded cavity structure again means that no action can be taken on the individual failure.

For a COB implementation using thin film layers as electrical contacts it is important to avoid air- or vacuum bubbles residing in the optical encapsulant or in the adhesion layers or in their interface towards other surfaces in the stack.

In many cases, the OLED or LED chip is mounted so that encapsulant material will reside in a space between the chip and the circuit board. If such encapsulant contains air bubbles and the circuit board undergoes a change in air pressure (e.g. during airplane shipping) the change in air pressure can affect the air bubble volume so that the OLED or LED chip looses electrical contact with the circuit board. Hence, it can be beneficial to apply the encapsulant in vacuum so that the amount of air trapped in the encapsulant, or between the encapsulant and structures in the cavity wall, is minimized. Alternatively the encapsulant can be degassed later.

The multilayer foil can be adhesively attached to the PCB, for example using an APF, such as a pressure sensitive adhesive (PSA). Such adhesives are commonly used in the electronics industry.

Alternatively, an APF can be a thermoplastic adhesive, which can be softened at a certain temperature and pressure. This allows the adhesive film to adapt its shape to e.g. a non-flat substrate having electrical contacts, or to a highly irregular surface of the optical foil. Since the APF can reach a liquid-like state when heated, it can now fill these irregularities and hereby reduce the risk of air getting trapped between the adhesive and an interfacing surface. The process can be further improved by having the deposition performed in vacuum. The inventors have also found that these types of adhesives do not leave residues on the PCB. Thus, if the lamination turns out to be of bad quality, the APF can be removed, e.g. pealed off, and replaced, without having to scrap the OLED or LED chip or PCB.

Instead of soldering there are alternative means for attaching the LED chip to the PCB, for example:
Isotropic conductive adhesives which conducts in all directions, such as adhesives or glues with metal (e.g. silver) particles,
anisotropic conductive adhesive films which only conducts vertically to the film surface (due to the ordered distribution of conductive particles).
Resins having solid solder particles residing in it without mixing (like “oil in water”); such resin can be distributed under the whole chip, and when heated, the solder particles melt and surface tension makes them line up and group at the contacts providing electrical connection, while the rest of the resin holds the chip in place

In one exemplary embodiment solid state light sources such as RGB OLED's or LEDs are connected to e.g. soldered onto a PCB having electrical contacts. The multilayer foil can comprise an adhesive layer, such as a thermoplastic adhesive or PSA, an optical foil and a top layer. Holes corresponding to the LED positions can be made by substractive manufacturing such as by being cut out in the multilayer foil using laser cutting, ablated using laser ablation, cut using mechanical cutters or stamps etc. The multilayer foil is then placed onto the PCB so that solid state light source such as an OLED or LED is positioned in the center of each hole. The PCB is then fixed to the multilayer foil. Heat or pressure can be supplied to the circuit board and the multilayer stack so that the adhesive material such as a thermoplastic adhesive or a PSA can melt or adhere, respectively, and enter any irregularity in the optical foil and the PCB surface. An optical encapsulant, e.g. can now be distributed on top of the stack thereby filling the cavities, and excess optical encapsulant can be removed with a squeegee or blade or the like. Optionally, the optical encapsulant can contain visible light scattering particles or visible light absorbing particles 36—see FIG. 4, filler material, e.g. micro particles.

1-18. (canceled)

19. An OLED or LED array for imaging applications mounted on a substrate comprising:
a plurality of OLED or LED chips,
a multilayer foil having holes and being attached to the substrate with an adhesion promoting film,
an OLED or LED chip is disposed within each hole,
wherein the thickness of the foil being equal to or larger than the height of the disposed OLED or LED chip, each hole being filled with an optical encapsulant,
wherein walls of the holes in the foil define the structure that keeps the encapsulant around the OLED or LED chip in a direction perpendicular to the substrate,
the multilayer foil having an uppermost layer and the optical encapsulant is flush with the uppermost layer of the multilayer foil, and
each hole is defined by the wall and a spacing between the wall of each hole and the OLED or LED chip which is placed in each hole.

20. The OLED or LED array according to claim 19, wherein a part of the substrate is exposed in the spacing.

21. The OLED or LED array according to claim 19, wherein the wall of each hole extends down towards the substrate and touches the substrate all around the hole.

22. The OLED or LED array according to claim 19, wherein the uppermost layer in the multilayer foil is absorbing for visible light.

23. The OLED or LED array according to claim 19, wherein the multilayer foil comprises an absorbing layer for visible light or a reflecting layer for visible light.

24. The OLED or LED array according to claim 19, wherein the optical encapsulant comprises visible light absorbing particles, wherein a pixel comprises the optical encapsulant layer with the visible light absorbing particles, the substrate and the OLEDs or LEDs.

25. The OLED or LED array according to claim 19, wherein the optical encapsulant comprises visible light scattering particles, wherein a pixel comprises the optical encapsulant layer with the visible light scattering particles, the substrate and the OLEDs or LEDs.

26. The OLED or LED array according to claim 25, wherein visible light scattering particles determine an angular distribution of light emitted from a cavity.

27. The OLED or LED array according to claim 26, wherein the angular distribution has a Lambertian or cosine intensity profile.

28. A method for assembling an OLED or LED array comprising a PCB having OLEDs or LEDs mounted onto it, an adhesive multilayer foil having holes and an optical encapsulant, the method comprising the steps of:
placing the multilayer foil onto the PCB so that the OLEDs or LEDs are positioned in the holes,
laminating the multilayer foil onto the PCB,
applying optical encapsulant on top of the multilayer foil and removing any excess encapsulant, and
curing the optical encapsulant, the multilayer foil having an uppermost layer and the optical encapsulant being flush with the uppermost layer of the multilayer foil,
wherein each hole is defined by a wall and a spacing between the wall of each hole and the OLED or LED which is placed in each hole.

29. The method according to claim 28, wherein a part of the substrate is exposed in the spacing.

30. The method according to claim 28, wherein the wall of each hole extends down towards the substrate and touches the substrate all around the hole.

31. The method according to claim 28, wherein the step of applying the optical encapsulant comprises any of heat curing the optical encapsulant, photocuring the encapsulant and room temperature curing of the encapsulant.

32. The method according claim 31, wherein the step of applying the optical encapsulant comprises applying the optical encapsulant under vacuum.

33. The method according to claim 28, wherein after the multilayer foil has been placed on the PCB and before the optical encapsulant has been cured, the multilayer foil is removed, the optical encapsulant, if any is present, is removed, and any failed component is replaced, a new multilayer foil having holes is placed onto the PCB so that the OLED's or LED's are positioned in the holes, the multilayer foil is laminated onto the PCB, optical encapsulant is applied on top of the multilayer foil and any excess encapsulant removed, and the optical encapsulant cured.

34. The method according to claim 28, wherein the adhesive multilayer foil comprises an adhesion promoter film.
